(19) United States
(12) Patent Application Publication
(10) Pub. No.: US 2024/0381548 A1
(43) Pub. Date: Nov. 14, 2024

(54) SWITCH CABINET ARRANGEMENT HAVING A HOUSING, ELECTROCHEMICAL ENERGY STORAGE ACCOMMODATED THEREIN AND EXTINGUISHING SYSTEM

(71) Applicant: RITTAL GMBH & CO. KG, Herborn (DE)

(72) Inventors: Philipp MUELLER, Freudenberg (DE); Barbara MÜLLER, Daaden (DE); Andreas WIRTH, Bad-Endbach (DE); Markus WEBER, Waldbrunn (DE)

(21) Appl. No.: 18/294,584

(22) PCT Filed: Aug. 1, 2022
(86) PCT No.: PCT/DE2022/100553

§ 371 Date: Feb. 2, 2024

(30) Foreign Application Priority Data
Aug. 27, 2021 (DE) 10 2021 122 271.0

(51) Int. Cl. H05K 5/02; A62C 3/16; A62C 99/00

(52) U.S. Cl. CPC H05K 5/0215; A62C 3/16; A62C 99/0018

(57) ABSTRACT

A switch cabinet arrangement having at least one housing and at least one electrochemical energy storage accommodated therein and an extinguishing system, wherein at least one gas-permeable membrane is arranged in each case on at least two outer walls of the at least one housing, diametrically opposite one another, via which a gas atmosphere in the interior of the at least one housing is fluidically connected to a gas atmosphere in the surroundings of the at least one housing.

### CROSS-REFERENCE TO RELATED APPLICATIONS

This application is a U.S. National Phase Application under 35 U.S.C. 371 of International Application No. PCT/DE2022/100553, filed on Aug. 1, 2022, which claims the benefit of German Patent Application No. 10 2021 122 271.0, filed on Aug. 27, 2021. The entire disclosures of the above applications are incorporated herein by reference.

### BACKGROUND

This section provides background information related to the present disclosure which is not necessarily prior art.

### TECHNICAL FIELD

The invention is based on a switch cabinet arrangement having at least one housing and at least one electrochemical energy storage accommodated therein and an extinguishing system likewise accommodated in the housing. Such a switch cabinet arrangement is described in EP 2 076 317 B1. A similar switch cabinet arrangement is also described in DE 10 2006 010 360 B3.

### DISCUSSION

In the case of IT applications, a so-called uninterruptible power supply (UPS) having electrochemical energy storages, such as batteries or accumulators, is frequently used to protect the energy supply of servers. These electrochemical energy storages have to be ventilated in accordance with the standard DIN EN 62485-2. In addition, an extinguishing system is used for fire protection. For the compact construction, both systems are frequently arranged in the same housing. When the extinguishing system is triggered, an extinguishing gas flows out and floods the housing. In order to ensure a sufficiently high concentration of the extinguishing gas in the housing for optimum fire inhibition, it is necessary for the cabinet to be as fluidically sealed as possible. On the other hand, the best possible sealing of the housing or of the switch cabinet arrangement with respect to the surroundings is likewise necessary in order to achieve a desired IP protection class.

Accordingly, the ventilation requirement in accordance with DIN EN 6248-2 is in competition with the tightness of the housing required for maintaining the extinguishing gas concentration and achieving a high IP protection class. In order to solve this problem, electrically actuatable closure flaps in outer walls of the housing are known from the prior art, but these require complex electrical actuation. Furthermore, these electrically actuatable closure flaps have a comparatively high structural depth, with which they project into the housing, and are cost-intensive.

### SUMMARY

This section provides a general summary of the disclosure and is not a comprehensive disclosure of its full scope or all of its features.

It is therefore one aspect of the invention to provide a switch cabinet arrangement which, on the one hand, provides the ventilation of the interior space required for equipping with batteries and, on the other hand, ensures in the event of fire that the extinguishing gas flooding the housing is maintained with a sufficiently high concentration for optimum fire inhibition.

Accordingly, it is provided that at least one gas-permeable membrane is arranged in each case on at least two outer walls of the at least one housing, diametrically opposite one another, via which a gas atmosphere in the interior of the at least one housing is fluidically connected to a gas atmosphere in the surroundings of the at least one housing. The gas permeability of the membrane, for example its porosity, can be set such that a gas of an extinguishing agent, which comprises (much) larger molecules compared to hydrogen, cannot pass through the membrane. This in turn means that even liquids, in particular water, cannot pass through the membrane. The porosity can be set, for example, via the density and the opening cross section of a plurality of fibrils of the membrane.

For example, a first membrane can be arranged at a lowermost point and a second membrane can be arranged at an uppermost point of a housing, for example of a switch cabinet, an uninterruptible power supply (UPS) or a cooling device (liquid cooling package-LCP). In this way, a diagonal air flow can arise as a result of natural, potential pressure differences. The membrane can be configured to allow air to pass through and otherwise to prevent water from penetrating through it, thus ensuring a high IP protection class of the switch cabinet arrangement. Otherwise, the membrane can be configured to block the comparatively very long-chain organic molecules of a gaseous extinguishing agent compared to air and hydrogen and thus prevent them from emerging from the switch cabinet arrangement in the event of fire. A suitable membrane is described in EP 2 404 652 B1. The membrane can be part of a pressure compensation plug. A suitable pressure compensation plug is sold under the trade name PMF 200542 by the company W. L. Gore Associates GmbH.

Accordingly, the gas-permeable membranes can be permeable to at least hydrogen gas (H₂) and impermeable to liquid, in particular to water. Furthermore, the gas-permeable membranes can have a greatly reduced permeability at least compared to the permeability for the hydrogen gas. This differentiation in permeability is possible in particular because the hydrogen gas, on the one hand, has a very small molecule size and, on the other hand, the extinguishing gases are frequently long-chain (organic) molecules.

Thus, in one embodiment of the invention, the membrane can comprise or consist of a microporous expanded polytetrafluoroethylene (ePTFE). The pore size of the membrane can accordingly be set precisely such that, on the one hand, a good permeability for hydrogen gas and, on the other hand, a greatly reduced permeability for the comparatively much larger molecules of the extinguishing gas is provided. Furthermore, by setting the pore size in the manner described above, it is ensured that the membrane is also impermeable to liquid, in particular to water.

For example, the gas-permeable membrane can comprise a plurality of fibrils having a diameter which is many times smaller than the diameter of a water droplet which could be applied to the switch cabinet arrangement and in particular the membrane in the application, for example when the switch cabinet arrangement is exposed to weather.

The at least one membrane can have a gas permeability to air of at least 14-16 l/min at an overpressure of 10-12 mbar in the interior of the switch cabinet arrangement with respect to the surroundings of the switch cabinet arrangement.

The gas-permeable membrane can be permeable to hydrogen gas (H₂) and substantially impermeable to an extinguishing gas of the extinguishing system, preferably to long-chain carbon compounds, particularly preferably to the gas of perfluoro (2-methyl-3-pentanone) (C₆F₁₂O). The high difference in the gas permeability between the hydrogen and the extinguishing gas can be achieved in particular in that even low differential pressures >0 mbar are sufficient to widen the openings of the membrane sufficiently large for hydrogen molecules. Even at a maximum pressure surge of the extinguishing gas at the triggering moment of the extinguishing system, no significant drop in the concentration of the extinguishing gas could be detected experimentally. The gas permeability can be determined with the aid of a manometric method.

For example, the gas permeability to hydrogen gas (H₂) can be at least 5 times, preferably at least 10 times greater than to the extinguishing gas, in particular to C₆F₁₂O.

The gas-permeable membrane can be arranged in a fluidic transition of a pressure compensation valve. The pressure compensation valve can be designed, for example, as the pressure compensation plug described above.

The fluidic transition from the interior of the at least one housing to the surroundings of the at least one housing can be gas-permeable and gas-impermeable in the opposite direction.

The switch cabinet arrangement can have a plurality of housings which form a switch cabinet row of housings connected fluidically to one another. The housings can be a switch cabinet housing and/or a cooling device housing and/or an uninterruptible power supply and/or another housing which is customary in switch cabinet construction and can be integrated into a switch cabinet row. In this case, the two microporous membranes can be arranged in the outer wall of different housings of the switch cabinet row.

The extinguishing agent can be or comprise perfluoro (2-methyl-3-pentanone). As a long-chain molecule, it is retained by the membrane or allowed to pass through only with great delay, such that in the event of fire a minimum concentration of the extinguishing agent gas in the housing is maintained for a period required for extinguishing purposes.

The extinguishing system can have an extinguishing agent metering which is designed to meter an amount of extinguishing agent, preferably perfluoro (2-methyl-3-pentanone), into the interior of the switch cabinet arrangement in the event of extinguishing, which extinguishing agent metering generates an atmospheric overpressure of at least 25 to 65 mbar, preferably of 35 to 55 mbar and particularly preferably of 40 to 50 mbar in the interior of the at least one housing with respect to the surroundings of the switch cabinet arrangement.

The membrane can be designed to maintain the overpressure, preferably at least 80%, for at least 3 minutes, preferably for at least 5 minutes and particularly preferably for at least 12 minutes.

A concentration of the extinguishing agent in the atmosphere in the housing can be at least 5%, preferably at least 6% and particularly preferably at least 8% in the event of extinguishing, wherein the membrane is designed to maintain the concentration, preferably at least 80%, for at least 3 minutes, preferably for at least 5 minutes and particularly preferably for at least 12 minutes.

A baffle plate can be arranged in the interior of the housing upstream of an extinguishing agent outlet of the extinguishing system. The baffle plate can be designed to improve the distribution of the extinguishing gas in the interior of the switch cabinet arrangement.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations and are not intended to limit the scope of the present disclosure.

Further details of the invention are explained with reference to the figures below. In the figures:

FIG. 1 shows a first embodiment of a switch cabinet arrangement according to the invention; and

FIG. 2 shows a second embodiment of a switch cabinet arrangement according to the invention.

### DETAILED DESCRIPTION

Example embodiments will now be described more fully with reference to the accompanying drawings.

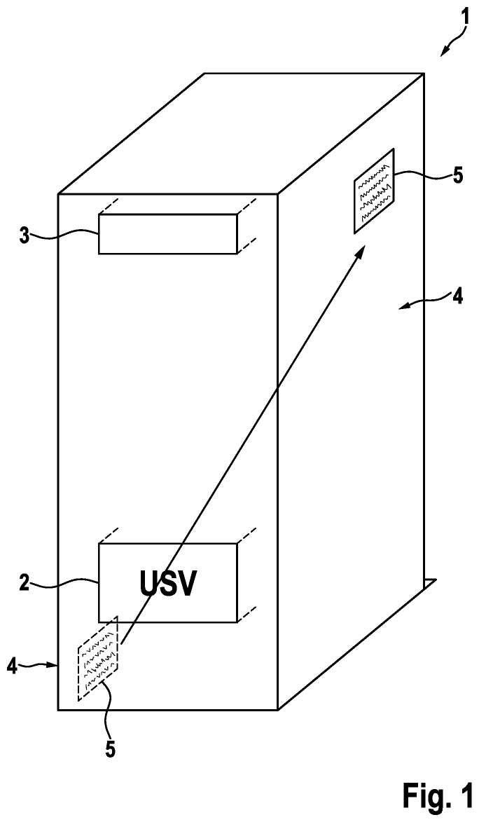

FIG. 1 shows a first exemplary embodiment of a switch cabinet arrangement according to the invention which consists of a single housing 1, for example of a switch cabinet housing. An uninterruptible power supply (UPS) 2 and an extinguishing system 3 are furthermore arranged in the switch cabinet housing in addition to the components (not shown) of an electrical switching system or server installations of an IT environment. An exemplary extinguishing system is described in all details in EP 2 076 317 B1. The extinguishing system 3 is designed to flood the switch cabinet housing with an extinguishing gas as a result of a detected fire development in the interior of the switch cabinet. In order to develop a sufficient extinguishing effect, it must be ensured that the extinguishing gas is maintained with a sufficient concentration in the interior of the switch cabinet housing over a sufficient period of time. For this purpose, it is essential that the interior of the switch cabinet housing is designed to be substantially fluidically sealed with respect to the environment of the switch cabinet housing 1.

The gas tightness required for fighting fire is in conflict with the legally prescribed ventilation of housings which contain batteries, for example an UPS 2. The ventilation requirement is furthermore in competition with the requirement, which exists for electrical switching systems and IT environments, of achieving the highest possible IP protection class.

In order to solve this problem, the embodiment according to FIG. 1 proposes that a membrane 5 is arranged in each case on opposite side walls 4 of the switch cabinet housing 1, diametrically opposite one another, which membrane is permeable to outgassing of the UPS in the event of failure, but is sufficiently impermeable to an extinguishing gas of the extinguishing system 3. If the membrane 5 is impermeable to an extinguishing gas of the extinguishing system 3, it is also impermeable to liquids, in particular water, in order to achieve the desired IP protection class.

The membranes 5 are at a maximum distance from one another within the switch cabinet housing, in order to allow the highest possible pressure difference for the natural through-ventilation of the switch cabinet housing. Accordingly, a first membrane is arranged in a lower region of the side wall on the front side of the housing 1, while a second membrane 5 is arranged on the opposite side wall 4, an upper end of the latter and on a rear side of the housing 1. The membranes 5 can be designed, for example, as a pressure compensation filter, as described, for example, in EP 2 404 652 B1.

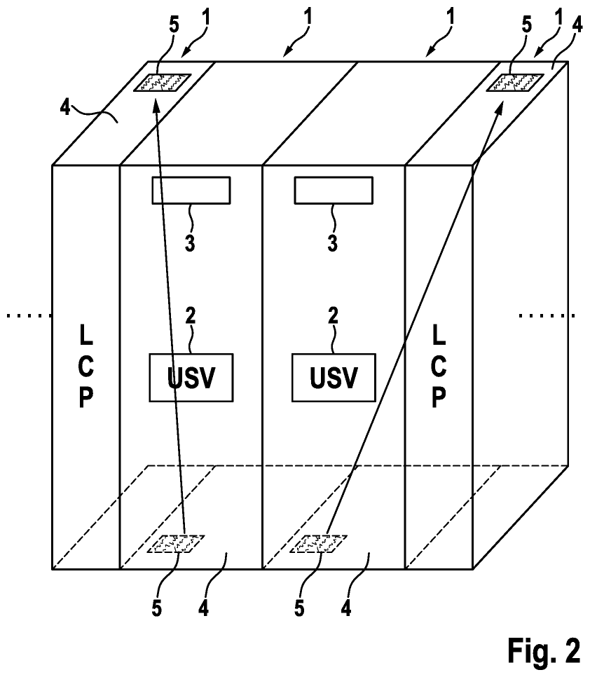

FIG. 2 shows a switch cabinet arrangement which forms a switch cabinet row, consisting of two central housings 1 which each have an UPS 2 and an extinguishing system 3 and, on the outside and adjacent to the latter, in each case one housing 1 with a cooling device (liquid cooling package-LCP). In this embodiment, the membranes 5 are distributed among the different housings 1, wherein, as can be seen, each housing 1 has only one membrane 5. Two first membranes 5 for the air inlet are arranged in the base of the UPS 2, while two second membranes 5 are arranged in the roof element of the LCP housings 1. On account of natural temperature fluctuations, natural through-ventilation of the switch cabinet arrangement can be achieved with the aid of this arrangement of the membranes, analogously to the individual housing arrangement according to FIG. 1.

The solutions described have the advantage of being able to be retrofitted in a particularly space-saving and cost-effective manner. A continuous exchange of air between the interior of the switch cabinet and the surroundings can take place via the membranes. Since hydrogen (H₂) is the smallest molecule, this is discharged directly during the outgassing from the batteries of the UPS 2 and an associated pressure increase in the interior of the switch cabinet, such that no explosive mixture can arise in the interior of the switch cabinet.

The membranes 5 furthermore allow a sufficiently long holding time of the extinguishing agent in the interior of the switch cabinet arrangement to be ensured in the event of fire after the triggering of the extinguishing system 3.

The features of the invention disclosed in the above description, in the drawing and in the claims can be essential both individually and in any desired combination for the realization of the invention.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-15. (canceled)

16. A switch cabinet arrangement comprising at least one housing and at least one electrochemical energy storage accommodated therein and an extinguishing system, wherein at least one gas-permeable membrane is arranged in each case on at least two outer walls of the at least one housing, diametrically opposite one another, via which a gas atmosphere in the interior of the at least one housing is fluidically connected to a gas atmosphere in the surroundings of the at least one housing, wherein a gas permeability of the membrane is set such that the gas of an extinguishing agent of the extinguishing system, which has larger molecules than hydrogen, cannot pass through the membrane.

17. The switch cabinet arrangement according to claim 16, in which the gas-permeable membranes are permeable to at least hydrogen gas (H₂) and impermeable to liquid, in particular water.

18. The switch cabinet arrangement according to claim 16, in which the membrane comprises or consists of a microporous expanded polytetrafluoroethylene (ePTFE).

19. The switch cabinet arrangement according to claim 16, in which the gas-permeable membrane comprises a plurality of fibrils having a diameter which is many times smaller than the diameter of a water droplet.

20. The switch cabinet arrangement according to claim 16, in which the at least one membrane has a gas permeability to air of at least 14 l/min at an overpressure of 10-12 mbar in the interior of the switch cabinet arrangement with respect to the surroundings of the switch cabinet arrangement.

21. The switch cabinet arrangement according to claim 16, in which the gas-permeable membrane is permeable to hydrogen gas (H₂) and substantially impermeable to an extinguishing gas of the extinguishing system, preferably to long-chain carbon compounds, particularly preferably to the gas of perfluoro (2-methyl-3-pentanone) (C₆F₁₂O).

22. The switch cabinet arrangement according to claim 16, in which the gas permeability to hydrogen is at least 5 times, preferably at least 10 times greater than to the extinguishing gas.

23. The switch cabinet arrangement according to claim 16, in which the gas-permeable membrane is arranged in a fluidic transition of a pressure compensation valve.

24. The switch cabinet arrangement according to claim 22, in which the fluidic transition from the interior of the at least one housing to the surroundings of the at least one housing is gas-permeable and gas-impermeable in the opposite direction.

25. The switch cabinet arrangement according to claim 16, in which a plurality of housings form a switch cabinet row with housings connected fluidically to one another, wherein the two microporous membranes are arranged in the outer wall of different housings of the switch cabinet row.

26. The switch cabinet arrangement according to claim 16, in which the extinguishing agent is or comprises perfluoro (2-methyl-3-pentanone).

27. The switch cabinet arrangement according to claim 16, in which the extinguishing system has an extinguishing agent metering which is designed to meter an amount of extinguishing agent, preferably perfluoro (2-methyl-3-pentanone), into the interior of the switch cabinet arrangement in the event of extinguishing, which extinguishing agent metering generates an atmospheric overpressure of at least 25 mbar, preferably of at least 35 mbar and particularly preferably of at least 40 mbar in the interior of the at least one housing with respect to the surroundings of the switch cabinet arrangement.

28. The switch cabinet arrangement according to claim 27, in which the membrane is designed to maintain the overpressure for at least 3 minutes, preferably for at least 5 minutes and particularly preferably for at least 12 minutes.

29. The switch cabinet arrangement according to claim 16, in which a concentration of the extinguishing agent in the event of extinguishing is at least 5%, preferably at least 6% and particularly preferably at least 8%, wherein the membrane is designed to maintain the concentration preferably for at least 3 minutes, preferably for at least 5 minutes and particularly preferably for at least 12 minutes.

30. The switch cabinet arrangement according to claim 16, in which a baffle plate is arranged in the interior of the housing upstream of an extinguishing agent outlet of the extinguishing system.
